(19) United States
(12) Patent Application Publication
(10) Pub. No.: US 2026/0005168 A1
(43) Pub. Date: Jan. 1, 2026

(54) SEMICONDUCTOR DEVICE INCLUDING BONDING OF STACKED STRUCTURE PARTS AND METHOD OF FABRICATING THE SAME

(71) Applicant: SK hynix Inc., Icheon-si (KR)

(72) Inventors: Won Tae KOO, Icheon-si (KR); Mir IM, San Jose, CA (US)

(21) Appl. No.: 18/960,820

(22) Filed: Nov. 26, 2024

(30) Foreign Application Priority Data
Jun. 27, 2024 (KR) 10-2024-0084868

(51) Int. Cl. H01L 23/00; H01L 25/065; H10B 80/00

(52) U.S. Cl. CPC H01L 24/05; H01L 24/08; H01L 24/80; H01L 25/0657; H10B 80/00; H01L 2224/05026; H01L 2224/05082; H01L 2224/05193; H01L 2224/05564; H01L 2224/05567; H01L 2224/05647; H01L 2224/08147; H01L 2224/80234; H01L 2225/06513; H01L 2924/1438

(57) ABSTRACT

A semiconductor device according to an embodiment includes a first stacked structure and a second stacked structure that are bonded to each other. The first stacked structure includes a first base body and a first connection structure disposed on a surface over the first base body. The second stacked structure includes a second base body and a second connection structure disposed on a surface over the second base body. Each of the first and second connection structures includes a connection pad, a carbon-based barrier layer disposed on the connection pad, and a bonding layer disposed on the carbon-based barrier layer and coupling the first and second connection structures to each other.

### CROSS-REFERENCE TO RELATED APPLICATION

The present application claims priority under 35 U.S.C. § 119(a) to Korean Application No. 10-2024-0084868, filed in the Korean Intellectual Property Office on Jun. 27, 2024, which is incorporated herein by reference in its entirety.

### BACKGROUND

### 1. Technical Field

The present disclosure generally relates to a semiconductor device and a method of fabricating the same and, more particularly, to a semiconductor device including bonding of stacked structure parts and a method of fabricating the same.

### 2. Related Art

Recently, as one method of fabricating a semiconductor device, a method has been proposed in which different integrated circuits are formed on first and second substrates, and then the first and second substrates are bonded to electrically connect the different integrated circuits to each other.

Specifically, the first and second substrates may be bonded to each other by forming conductive pads, electrically connected to the integrated circuits of the first and second substrates, over the first and second substrates, and bonding the conductive pads to each other. The conductive pads of the first and second substrates can perform not only the function of electrically connecting the first substrate and second substrates to each other, but also the function of structurally bonding the first and second substrates to each other. Accordingly, the structural stability at bonding surfaces of the conductive pads of the first and second substrates can determine the electrical reliability of the semiconductor device.

### SUMMARY

A semiconductor device according to an embodiment of the present disclosure may include a first stacked structure and a second stacked structure that are bonded to each other. The first stacked structure may include a first base body and a first connection structure disposed on a surface over the first base body. The second stacked structure may include a second base body and a second connection structure disposed on a surface over the second base body. Each of the first and second connection structures may include a connection pad, a carbon-based barrier layer disposed on the connection pad, and a bonding layer disposed on the carbon-based barrier layer and coupling the first and second connection structures to each other.

A semiconductor device according to another embodiment of the present disclosure may include a first substrate structure part and a second substrate structure part that are bonded to each other. The first substrate structure part may include a first substrate, a memory cell driving circuit disposed on the first substrate, and a first connection structure disposed over the substrate and electrically connected to the memory cell driving circuit. The second substrate structure part may include a second substrate, a memory cell structure disposed on the second substrate, and a second connection structure disposed over the substrate and electrically connected to the memory cell structure. Each of the first and second connection structures may include a connection pad, a carbon-based barrier layer disposed on the connection pad, and a bonding layer disposed on the carbon-based barrier layer and coupling the first and second connection structures to each other.

There is disclosed a method of fabricating a semiconductor device according to another embodiment of the present disclosure. In the method, a first substrate structure part including a first substrate and a first connection structure disposed on the first substrate may be formed. The first connection structure may include a first connection pad, a carbon-based first heater electrode disposed on the first connection pad, and a first preliminary bonding layer disposed on the carbon-based first heater electrode. A second substrate structure part including a second substrate and a second connection structure disposed on the second substrate may be formed. The second connection structure may include a second connection pad, a carbon-based second heater electrode disposed on the second connection pad, and a second preliminary bonding layer disposed on the carbon-based second heater electrode. The first connection structure and the second connection structure may be bonded to each other through a rapid thermal-treatment to couple the first substrate structure and the second substrate structure.

### BRIEF DESCRIPTION OF THE DRAWINGS

FIG. 1 is a schematic cross-sectional view illustrating a semiconductor device according to an embodiment of the present disclosure.

FIG. 2 is a flowchart schematically illustrating a method of fabricating a semiconductor device according to an embodiment of the present disclosure.

FIG. 3 through FIG. 9 are schematic cross-sectional views illustrating a method of fabricating a semiconductor device according to an embodiment of the present disclosure.

FIG. 10 through FIG. 12 are schematic cross-sectional views illustrating a method of fabricating a semiconductor device according to another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or customs of a user or operator in the technical field. The meanings of the terms used follow the definitions defined when specifically defined herein, and may be interpreted as meanings generally recognized by those skilled in the art in the absence of specific definitions.

In addition, when describing a method or a fabricating method, each process constituting the method may be performed in a different order from the stated order unless a specific order is clearly stated in the context. That is, the processes may proceed in the same order as stated, may proceed substantially simultaneously, or may proceed in the opposite order.

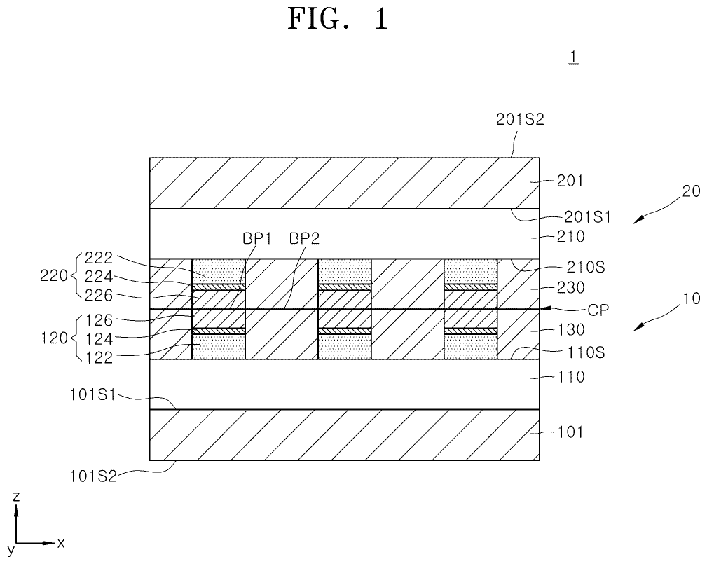

FIG. 1 is a schematic cross-sectional view illustrating a semiconductor device according to an embodiment of the present disclosure. Referring to FIG. 1, a semiconductor device 1 includes a first stacked structure part 10 and a second stacked structure part 20 that are bonded to each other. The first and second stacked structure parts 10 and 20 are bonded to each other at a bonding surface (CP).

The first stacked structure part 10 includes a first base body 101 and first connection structures 120 disposed on a surface 110S over the first base body 101. In addition, the first stacked structure part 10 includes a first bonding insulation layer 130 disposed in a lateral direction (for example, x-direction or y-direction) on the surface 110S over the first base body 101. The first bonding insulation layer 130 is disposed to surround the first connection structures 120.

Likewise, the second stacked structure part 20 includes a second base body 201 and second connection structures 220 disposed on a surface 210S over the second base body 201. Additionally, the second stacked structure part 20 includes a second bonding insulation layer 230 disposed in the lateral direction (for example, x-direction or y-direction) on the surface 210S over the second base body 201. The second bonding insulation layer 230 is disposed to surround the second connection structures 220.

Referring to FIG. 1, the bonding surface CP of the first stacked structure part 10 and the second stacked structure part 20 includes a first interface BP1 between the first connection structures 120 and the second connection structures 220, and a second interface BP2 between the first bonding insulation layer 130 and the second bonding insulation layer 230. The first connection structures 120 and the second connection structures 220 form conductive bonding at the first interface BP1, and the first bonding insulation layer 130 and the second bonding insulation layer 230 form insulating bonding at the second interface BP2.

Referring to FIG. 1, the first base body 101 may be a supporting structure of the semiconductor device 1. The first base body 101 may be, for example, a substrate or a thin film structure. The first base body 101 may include, for example, a semiconductor, a conductor, or an insulator.

In an embodiment, the first base body 101 may be a semiconductor substrate. As an example, the semiconductor substrate may be doped with an n-type dopant or a p-type dopant. The first base body 101 includes a first surface 101S1 and a second surface 101S2 opposite to the first surface 101S1. The first base body 101 may include a well region doped with an n-type dopant or a p-type dopant formed in an active region, which is an internal region adjacent to the first surface 101S1.

A first device structure 110 is disposed on the first surface 101S1 of the first base body 101. The first device structure 110 may include a plurality of levels of conductive layers, conductive contact patterns connecting the plurality of levels of conductive layers to each other, and an interlayer insulation layer between the conductive layers. In an embodiment, the first device structure 110 may include various integrated circuits. The integrated circuits may be a memory cell circuit, a peripheral logic circuit, or a wiring circuit. As an example, the integrated circuits may include a field effect transistor, a resistor element, a capacitor, or a combination of two or more thereof.

The first connection structures 120 are disposed on the surface 110S of the first device structure 110. The first connection structures 120 may be electrically connected to the memory cell circuits or the peripheral logic circuits of the first device structure 110. In addition, the first connection structures 120 may be electrically connected to the well region of the first base body 101 via the wiring circuits of the first device structure 110.

The first connection structures 120 includes a first connection pad 122, a first carbon-based barrier layer 124, and a first bonding layer 126. The first connection pad 122 may be a conductive pattern disposed on the surface 110S of the first device structure 110. As an example, the first connection pad 122 may include copper (Cu), aluminum (Al), tungsten (W), titanium (Ti), tantalum (Ta), titanium nitride, tantalum nitride, tungsten nitride, or a combination of two or more thereof.

Referring to FIG. 1, the first carbon-based barrier layer 124 is disposed on the first connection pad 122. The first carbon-based barrier layer 124 performs a barrier function to block or mitigate material movement between the first connection pad 122 and the first bonding layer 126. In an embodiment, the first carbon-based barrier layer 124 may include graphene. The graphene may have a two-dimensional structure in the shape of a honeycomb in which carbon atoms are arranged at the corners of a hexagon. The graphene may be composed of a film with a thickness of one atom. As an example, the graphene may have a thickness of about 0.2 nm. In an embodiment, the first carbon-based barrier layer 124 may be formed of a single layer of graphene, or may include multiple layers of graphene. As an example, the first carbon-based barrier layer 124 may have a thickness of 0.2 nm through 10 nm.

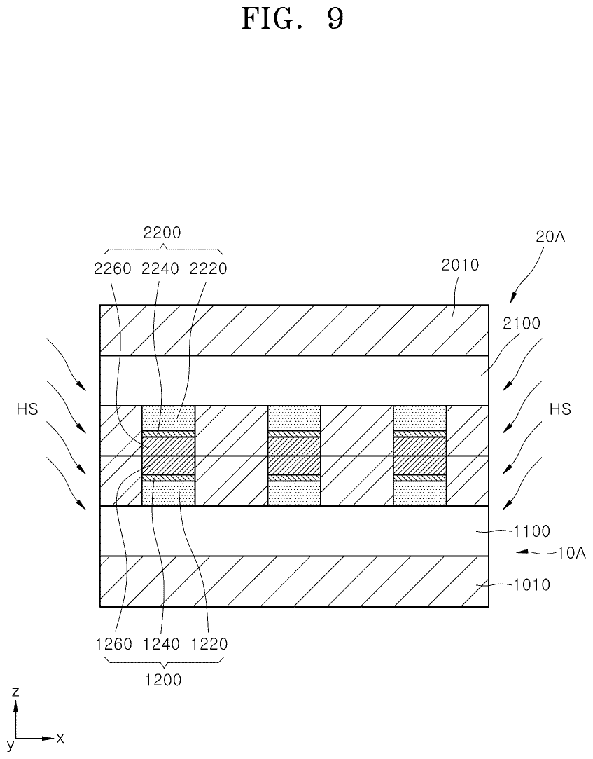

The first carbon-based barrier layer 124 may serve as a heater electrode that absorbs energy from a heat source HS to generate heat in a rapid heat treatment process described later with reference to FIG. 9. In addition, the first carbon-based barrier layer 124 has high thermal conductivity, so that the first carbon-based barrier layer 124 can uniformly transfer the heat generated internally through the rapid heat treatment process to the first bonding layer 126.

Referring to FIG. 1, the first bonding layer 126 is disposed on the first carbon-based barrier layer 124. The first bonding layer 126 forms the first interface BP1 with a second bonding layer 226 of the second connection structure 220. The first bonding layer 126 may include a conductive bonding material. The first bonding layer 126 may include, for example, copper (Cu), a binary copper alloy, a high-entropy alloy (HEA) of quaternary or more, or a combination of two or more thereof. The binary copper alloy may include, for example, a copper-titanium (Cu—Ti) alloy or a copper-aluminum (Cu-AI) alloy. The HEA of quaternary or more may include, for example, at least four or more metals selected from copper (Cu), nickel (Ni), iron (Fe), chromium (Cr), platinum (Pt), silver (Ag), palladium (Pd), cobalt (Co), titanium (Ti), zirconium (Zr), and hafnium (Hf). The four or more metals may be combined in substantially the same amounts within the high-entropy alloy (HEA). In an embodiment, the high-entropy alloy (HEA) may be a single-phase solid state solution formed of a metal of quaternary or more.

The first bonding insulation layer 130 is disposed on the surface 110S of the first device structure 110. The first bonding insulation layer 130 may fill spaces between the first connection structures 120 in the lateral direction (for example, x-direction or y-direction). The first bonding insulation layer 130 may include, for example, oxide, nitride, oxynitride, or a combination of two or more thereof.

Referring back to FIG. 1, the second stacked structure part 20 is disposed on the first stacked structure part 10. The second stacked structure part 20 includes a second base body 201 having a first surface 201S1 and a second surface 201S2. The configuration of the second base body 201 may be substantially the same as the configuration of the first base body 101.

The second stacked structure part 20 includes a second device structure 210 disposed on the first surface 201S1 of the second base body 201. The second device structure 210 may include a plurality of levels of conductive layers, conductive contact patterns connecting the plurality of levels of conductive layers to each other, and an interlayer insulation layer between the conductive layers.

In an embodiment, the second device structure 210 may include various integrated circuits. The integrated circuits may include a memory cell circuit, a peripheral logic circuit, or a wiring circuit. In an embodiment, the second device structure 210 may include integrated circuits that are different from the integrated circuits of the first device structure 110. As an example, one of the first device structure 110 and the second device structure 210 includes memory cell circuits, while the other includes logic circuits that drive and control the memory cell circuits.

Referring back to FIG. 1, the second stacked structure part 20 includes the second connection structures 220 disposed on the surface 210S of the second device structure 210. Each of the second connection structures 220 includes a second connection pad 222, a second carbon-based barrier layer 224, and a second bonding layer 226. The configurations of the second connection pad 222, the second carbon-based barrier layer 224, and the second bonding layer 226 may be substantially the same as the configurations of the first connection pad 122, the first carbon-based barrier layer 124, and the first bonding layer 126 of the first connection structure 120. respectively.

In addition, the second bonding insulation layer 230 is disposed on the surface 210S of the second device structure 210. The second bonding insulation layer 230 may fill spaces between the second connection structures 220 in the lateral direction (for example, x-direction or y-direction). The configuration of the second bonding insulation layer 230 may be substantially the same as the configuration of the first bonding insulation layer 130.

As described above, in the semiconductor device 1, the first stacked structure part 10 and the second stacked structure part 20 are bonded to each other at the bonding surface CP. The first bonding layer 126 of each of the first connection structures 120 and the second bonding layer 226 of each of the second connection structures 220 are bonded to each other at the first interface BP1 to form an electrical connection portion of the semiconductor device 1. In addition, the first bonding insulation layer 130 and the second bonding insulation layer 230 are bonded to each other at the second interface BP2 to form an insulating bonding portion of the semiconductor device 1.

In an embodiment, each of the first connection structure 120 and second connection structure 220 includes the connection pad, the carbon-based barrier layer, and the bonding layer. The carbon-based barrier layer is disposed between the connection pad and the bonding layer to block or mitigate material movement between the connection pad and the bonding layer. Accordingly, in a thermal bonding process for the first stacked structure part 10 and the second stacked structure part 20 described later, the connecting portions of the first connection structures 120 and the second connection structures 220 can be chemically and structurally stabilized. Accordingly, the reliability of the electrical connection between the first connection structures 120 and the second connection structures 220 can be improved.

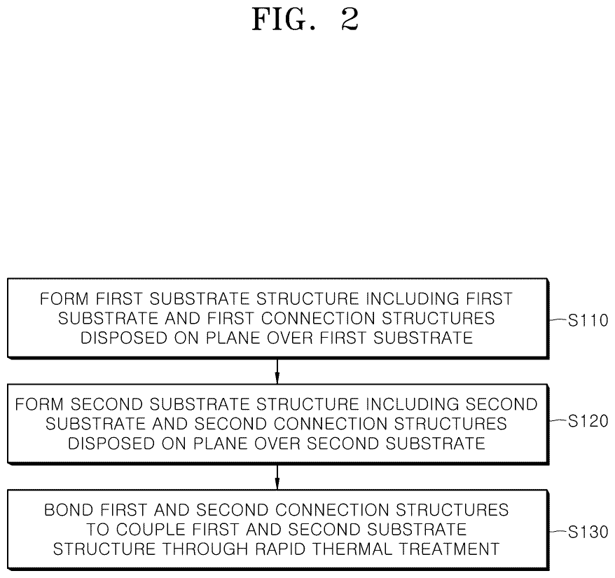

FIG. 2 is a flowchart schematically illustrating a method of fabricating a semiconductor device according to an embodiment of the present disclosure. The method of fabricating a semiconductor device of FIG. 2 may be applied to the fabrication of a semiconductor device 1 of FIG. 1.

Referring to S110 of FIG. 2, a first substrate structure including a first substrate and a first connection structure disposed on a plane over the first substrate is formed. In an embodiment, the first connection structure includes a first connection pad, a carbon-based first heater electrode disposed on the first connection pad, and a first preliminary bonding layer disposed on the first heater electrode.

Referring to S120 of FIG. 2, a second substrate structure including a second substrate and a second connection structure disposed on a plane over the second substrate is formed. In an embodiment, the second connection structure includes a second connection pad, a carbon-based second heater electrode disposed on the second connection pad, and a second preliminary bonding layer disposed on the second heater electrode.

Referring to S130 of FIG. 2, the first connection structure and the second connection structure are bonded to each other through rapid thermal treatment to couple the first substrate structure and the second substrate structure. In an embodiment, the first substrate structure and the second substrate structure are positioned so that the first preliminary bonding layer of the first substrate structure and the second preliminary bonding layer of the second substrate structure are in contact with each other. Next, the first substrate structure and second substrate structure are irradiated by a heat source performing rapid heating and cooling to thermally bond the first preliminary bonding layer and second preliminary bonding layer between the carbon-based first heater electrode and the carbon-based second heater electrode. A connection portion of the first and second bonding structures may be formed through the thermal bonding of the first preliminary bonding layer and the second preliminary bonding layer. In an embodiment, the heat source may include a microwave, a pulsed laser, intense pulse light, or a combination of two or more thereof.

Through the above-described process, a semiconductor device according to an embodiment of the present disclosure can be fabricated. According to an embodiment of the present disclosure, a pair of connection structures, each of which includes a connection pad, a carbon-based heater electrode, and a preliminary bonding layer, are bonded to each other through rapid thermal treatment to couple the first substrate structure and the second substrate structure. Each of the carbon-based heater electrodes performs a role of a heater generating heat and a barrier against material movement. Accordingly, the semiconductor device including a bonding interface of the first substrate structure and the second substrate structure with improved structural stability and electrical reliability can be provided.

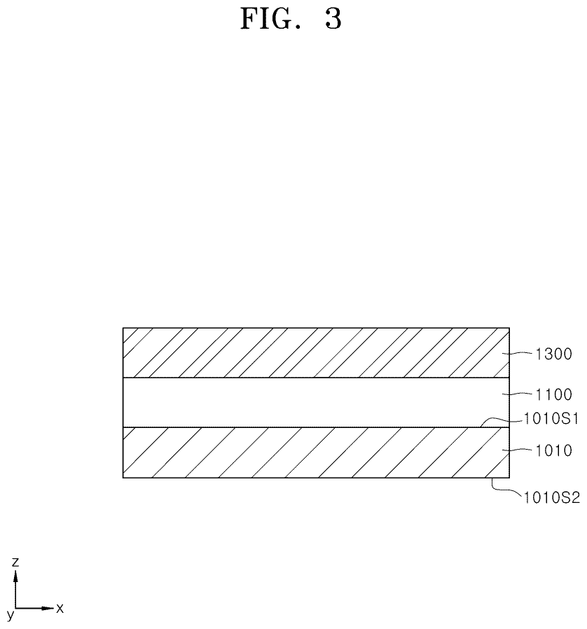

FIG. 3 through FIG. 9 are schematic cross-sectional views illustrating a method of fabricating a semiconductor device according to an embodiment of the present disclosure. The method of fabricating the semiconductor device of FIG. 3 through FIG. 9 may be applied to a method of fabricating a semiconductor device 1 described above with reference to FIG. 1.

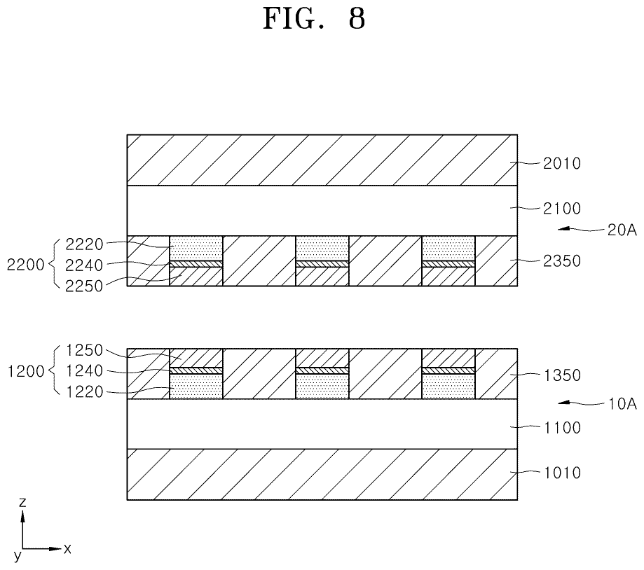

In an embodiment, the method of fabricating the semiconductor device includes operations of performing the processes related to FIG. 3 through FIG. 7 to fabricate a first substrate structure 10A and a second substrate structure 20B, and an operation of performing the process related to FIG. 8 and FIG. 9 to bond together the first substrate structure 10A and the second substrate structure 20B.

First, an operation of forming the first substrate structure 10A is described. The operation of forming the first substrate structure 10A corresponds to the operation S110 of the flowchart of FIG. 2. Referring to FIG. 3, a first substrate 1010 is provided. The first substrate 1010 may be formed of a material capable of being subjected to a semiconductor process. The first substrate 1010 may include, for example, a semiconductor, a conductor, or an insulator.

In an embodiment, the first substrate 1010 may be a semiconductor substrate doped with a p-type dopant or an n-type dopant. The first substrate 1010 has a first surface 1010S1 and a second surface 1010S2 opposite to the first surface 1010S1. The first substrate 1010 may include a doped well region formed in an active region, which is an internal region adjacent to the first surface 1010S1. The doped well region may be doped with the same or a different type of dopant as the first substrate 1010.

Next, a first device structure 1100 is formed on the first surface 1010S1 of the first substrate 1010. The first device structure 1100 may include a plurality of levels of conductive layers, conductive contact patterns connecting the plurality of levels of conductive layers to each other, and an interlayer insulation layer between the conductive layers. In an embodiment, the first device structure 1100 may include various integrated circuits. The integrated circuit may include a memory cell circuit, a peripheral logic circuit, or a wiring circuit. As an example, the integrated circuit may include a field effect transistor, a resistor element, a capacitor, or a combination of two or more thereof. The first device structure 1100 may be formed through a semiconductor integration process.

Next, a first upper insulation layer 1300 is formed on an upper surface of the first device structure 1100. The first upper insulation layer 1300 may include, for example, oxide, nitride, oxynitride, or a combination of two or more thereof.

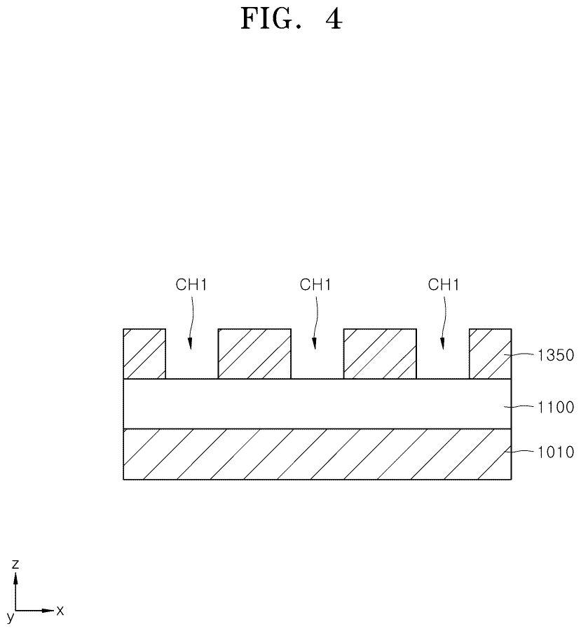

Referring to FIG. 4, the first upper insulation layer (1300 of FIG. 3) is patterned on the first device structure 1100 to form a first bonding insulation layer 1350 having first contact hole patterns CH1. The first contact hole patterns CH1 expose the first device structure 1100.

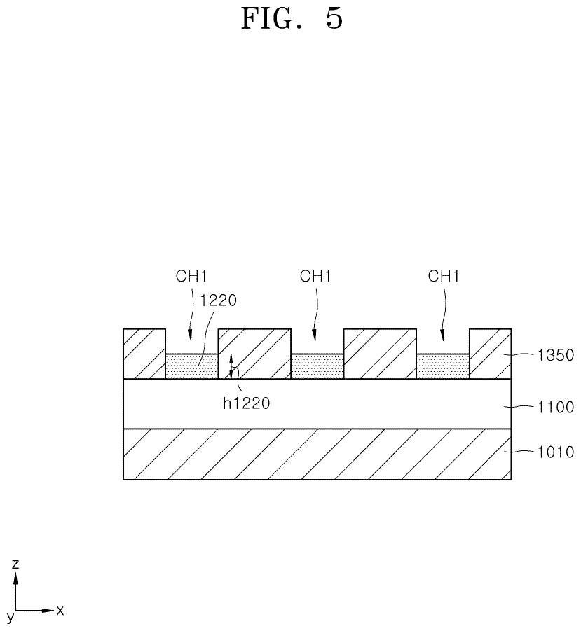

Referring to FIG. 5, a first pad layer 1220 having conductivity is formed inside the first contact hole patterns CH1. The first pad layer 1220 may include a conductive material, such as copper (Cu), aluminum (Al), tungsten (W), titanium (Ti), tantalum (Ta), titanium nitride, tantalum nitride, tungsten nitride, or a combination of two or more thereof. The first pad layer 1220 may be formed by a chemical vapor deposition method, an atomic layer deposition method, or the like.

In an embodiment, to form the first pad layer 1220, a conductive material layer is formed on the first device structure 1100 to fill the first contact hole patterns CH1 and is formed on the first bonding insulation layer 1350 outside the first contact hole patterns CH1. Next, a planarization process is performed for the conductive material layer until upper surfaces of the first bonding insulation layer 1350 are exposed. Accordingly, the conductive material layer formed on the first bonding insulation layer 1350 outside the first contact hole patterns CH1 is removed. Next, the conductive material layer formed inside the first contact hole patterns CH1 is etched to a predetermined thickness by applying an etch-back process, thereby forming a first pad layer 1220 having a predetermined height h1220.

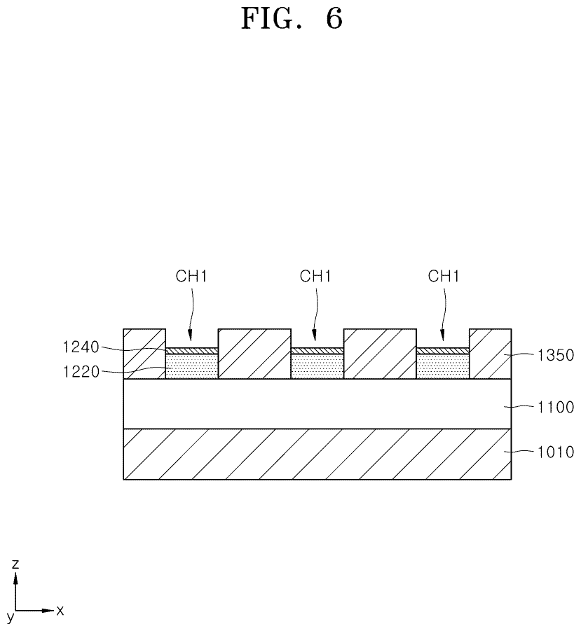

Referring to FIG. 6, a first electrode layer 1240 including graphene is formed on the first pad layer 1220 inside the first contact hole patterns CH1. The graphene may have a two-dimensional structure in the shape of a honeycomb in which carbon atoms are arranged at the corners of hexagon. The graphene may be composed of a film with a thickness of one atom. As an example, the graphene may have a thickness of about 0.2 nm.

In an embodiment, the operation of forming the first electrode layer 1240 may include a process of synthesizing graphene using a catalyst, and a process of transferring the synthesized graphene onto the first pad layer 1220. The process of synthesizing the graphene may include, for example, supplying a carbon source onto a catalyst metal and applying heat to the catalyst metal to grow the graphene on the catalyst metal. The catalytic metal may include, for example, copper (Cu), nickel (Ni), platinum (Pt), iridium (Ir), ruthenium (Ry), cobalt (Co), or a combination of two or more thereof. The carbon source may include a hydrocarbon. The hydrocarbon may include, for example, methane (CH₄), ethylene (C₂H₄), acetylene (C₂H₂), or a combination of two or more thereof. Subsequently, the grown graphene may be separated from the catalyst metal and then transferred onto the first pad layer 1220 to form the first electrode layer 1240.

In another embodiment, the operation of forming the first electrode layer 1240 may be performed by growing the graphene on the first pad layer 1220 using the conductive material of the first pad layer 1220 as a seed. In a specific embodiment, when the first pad layer 1220 includes a copper (Cu) layer, the graphene can be grown on the copper (Cu) layer by a chemical vapor deposition method. The chemical vapor deposition method may use a hydrocarbon as a source gas. The copper (Cu) layer may be used as a catalyst for the graphene growth. The hydrocarbon may include, for example, methane (CH₄), ethylene (C₂H₄), acetylene (C₂H₂), or a combination of two or more thereof. In an embodiment, the process of forming the first pad layer 1220 and the process of growing the graphene on the first pad layer 1220 may be performed continuously in-situ. The grown graphene may form the first electrode layer 1240.

The first electrode layer 1240 formed by the various methods described above may be formed of a single layer of the graphene, or may include multiple layers of the graphene. The first electrode layer 1240 is formed to cover the first pad layer 1220.

In an embodiment, the functional group positioned on the graphene surface of the first electrode layer 1240 can promote the chemical adsorption of the chemical species of the source gas onto the graphene in the process of forming a first bonding material layer 1250 described below, thereby improving the deposition rate and film uniformity of the first bonding material layer 1250. In addition, the functional group of the graphene of the first electrode layer 1240 can promote the absorption of thermal energy provided by the heat source HS during the rapid thermal treatment described later, thereby improving the heat generation characteristics of the first electrode layer 1240.

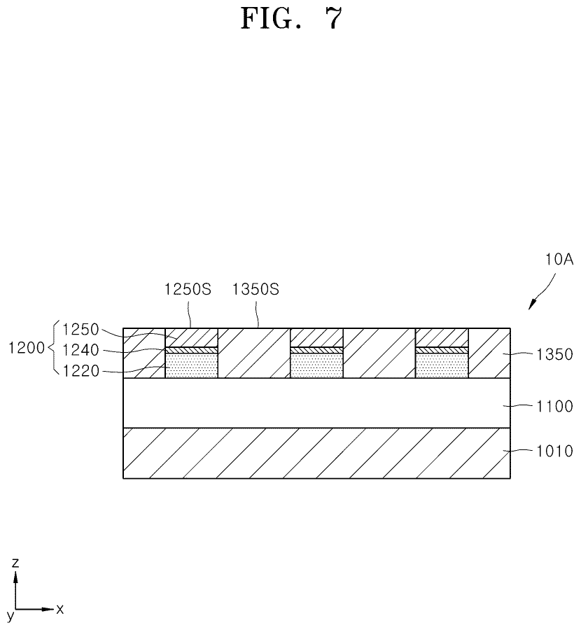

Referring to FIG. 7, the first bonding material layer 1250 is formed on the first electrode layer 1240 within the first contact hole patterns CH1. The first bonding material layer 1250 is formed to fill the interior of the first contact hole patterns CH1. The first bonding material layer 1250 may be a thin film including a metal. The first bonding material layer 1250 may include, for example, copper (Cu), a binary copper alloy, a high-entropy alloy of quaternary or more, or a combination of two or more thereof. The binary copper alloy may include, for example, a copper-titanium (Cu—Ti) alloy or a copper-aluminum (Cu-AI) alloy. The high-entropy alloy of quaternary or more may include, for example, at least four or more metals selected from copper (Cu), nickel (Ni), iron (Fe), chromium (Cr), platinum (Pt), silver (Ag), palladium (Pd), cobalt (Co), titanium (Ti), zirconium (Zr), and hafnium (Hf). The four or more metals may be combined in substantially the same amounts within the high-entropy alloy. In an embodiment, the high-entropy alloy may be a single-phase solid state solution composed of metals having four or more components.

In an embodiment, the first bonding material layer 1250 may be formed by forming a thin film including the metal that fills the interior of the first contact hole patterns CH1 and is also formed on the first bonding insulation layer 1350 outside the first contact hole patterns CH1. Different methods of forming the thin film may be used, such as for example, a chemical vapor deposition method, an atomic layer deposition method, a coating method, or a combination of two or more thereof. Subsequently, a planarization process is performed on the thin film until upper surfaces of the first bonding insulation layer 1350 are exposed. The planarization process may include a chemical mechanical polishing (CMP) method. Accordingly, the thin film formed on the first bonding insulation layer 1350 outside the first contact hole patterns CH1 is removed. As a result, an upper surface 1250S of the first bonding material layer 1250 may be positioned at substantially the same level as an upper surface 1350S of the first bonding insulation layer 1350. The first bonding material layer 1250 may be disposed inside the first contact hole patterns CH1.

Through the above-described methods, the first pad layer 1220, the first electrode layer 1240, and the first bonding material layer 1250 are sequentially formed to form the first connection structures 1200 on the first device structure 1100. The first pad layer 1220, the first electrode layer 1240, and the first bonding material layer 1250 of each of the first connection structures 1200 may correspond to the first connection pad, the carbon-based first heater electrode, and the first preliminary bonding layer of the first connection structure formed in the operation S110 of FIG. 2, respectively. In addition, through the above-described methods, the first substrate structure 10A including the first substrate 1010, and the first connection structures 1200 and the first bonding insulation layer 1350 that are disposed on a surface over the first substrate 1010 can be formed.

The second substrate structure 20A may be formed by performing the process substantially the same as the process described above with reference to FIG. 3 through FIG. 7. Referring to FIG. 8, the second substrate structure 20A includes a second substrate 2010, a second device structure 2100 formed over the second substrate 2010, and second connection structures 2200 and a second bonding insulation layer 2350 that are formed over the second device structure 2100. The configurations of the second substrate 2010, the second device structure 2100, the second connection structures 2200, and the second bonding insulation layer 2350 may be substantially the same as the configurations of the first substrate 1010, the first device structure 1100, the first connection structures 1200, and the first bonding insulation layer 1350 of the first substrate structure 10A, respectively. However, in an embodiment, the second device structure 2100 may include integrated circuits different from the integrated circuits of the first device structure 1100. As an example, one of the first device structure 1100 and the second device structure 2100 may include memory cell circuits, while the other may include logic circuits for driving and controlling the memory cell circuits.

Each of the second connection structures 2200 includes a second pad layer 2220, a second electrode layer 2240, and a second bonding material layer 2250 that are sequentially formed on the second device structure 2100. The configurations of the second pad layer 2220, the second electrode layer 2240, and the second bonding material layer 2250 may be substantially the same as the configurations of the first pad layer 1220, the first electrode layer 1240, and the first bonding material layer 1250 of the first connection structure 1200, respectively.

Referring to FIG. 8, the first substrate structure 10A and the second substrate structure 20A are disposed to be aligned with each other at a predetermined interval. The first bonding material layer 1250 of the first substrate structure 10A and the second bonding material layer 2250 of the second substrate structure 20A may be aligned to face each other, and the first bonding insulating layer 1350 of the first substrate structure 10A and the second bonding insulating layer 2350 of the second substrate structure 20A may be aligned to face each other.

Referring to FIG. 9, the first substrate structure 10A and the second substrate structure 20A are disposed such that the first bonding material layer 1250 and the second bonding material layer 2250 contact each other.

While the first substrate structure 10A and the second substrate structure 20A are in contact with each other in the above-described manner, a heat source HS that performs rapid heating and cooling irradiates the first substrate structure 10A and the second substrate structure 20A. The first bonding material layer 1250 and the second bonding material layer 2250 are rapidly melted and solidified between the first electrode layer 1240 and the second electrode layer 2240, thereby being thermally bonded to each other by the heat source HS. As a result, the first and second bonding material layers 1250 and 2250 are converted into first and second bonding layers 1260 and 2260, respectively, and accordingly, the first connection structures 1200 and the second connection structures 2200 can be bonded to each other.

According to an embodiment of the present disclosure, the heat source HS may include, for example, a microwave, a pulsed laser, intense pulse light, or a combination of two or more thereof. The rapid thermal treatment using the heat source HS may be performed in a vacuum atmosphere or in an inert gas atmosphere.

In an embodiment, the heat source HS can implement a heating and cooling rate of up to about 2000° C./s. As a result, the first bonding material layer 1250 and the second bonding material layer 2250 can be rapidly heated to the melting points and thermally treated by the heat source HS and then rapidly cooled. Additionally, the first bonding material layer 1250 and the second bonding material layer 2250 can be thermally-treated by the heat source HS for a short heating time of less than 1 millisecond (msec) to less than 10 seconds (sec) at the melting point.

Each of the first electrode layer 1240 and second electrode layer 2240 including graphene may perform the role of a heater electrode that absorbs the thermal energy of the heat source HS to generate heat during the rapid thermal treatment process. The functional group of the graphene in each of the first electrode layer 1240 and second electrode layer 2240 promotes the absorption of the thermal energy from the heat source HS during the rapid thermal treatment, thereby improving the heat generation characteristics of the first electrode layer 1240 and the second electrode layer 2240. In addition, each of the first electrode layer 1240 and the second electrode layer 2240 has high thermal conductivity to effectively transfer the heat generated internally during the rapid thermal treatment process to the first bonding material layer 1250 and the second bonding material layer 2250 at a uniform density during the short heating time. Accordingly, when the rapid thermal treatment is performed, heat damage to the first substrate structure 10A and the second substrate structure 20A can be reduced.

In addition, the graphene can maintain durability up to about 3000° C./s. Accordingly, during the rapid thermal treatment process, the first electrode layer 1240 including the graphene can maintain stable interfaces with the first bonding material layer 1250 and the first pad layer 1220, and the second electrode layer 2240 including the graphene can maintain stable interfaces with the second bonding material layer 2250 and the second pad layer 2220. Accordingly, the first electrode layer 1240 can block or mitigate material movement between the first pad layer 1220 and the first bonding material layer 1250, and the second electrode layer 2240 can block or mitigate material movement between the second pad layer 2220 and the second bonding material layer 2250. As a result, after the rapid thermal treatment, the structural stability and electrical reliability of each of the first pad layer 1220 and second pad layer 2220 can be maintained or improved.

Through the above-described method, semiconductor devices according to embodiments of the present disclosure can be fabricated.

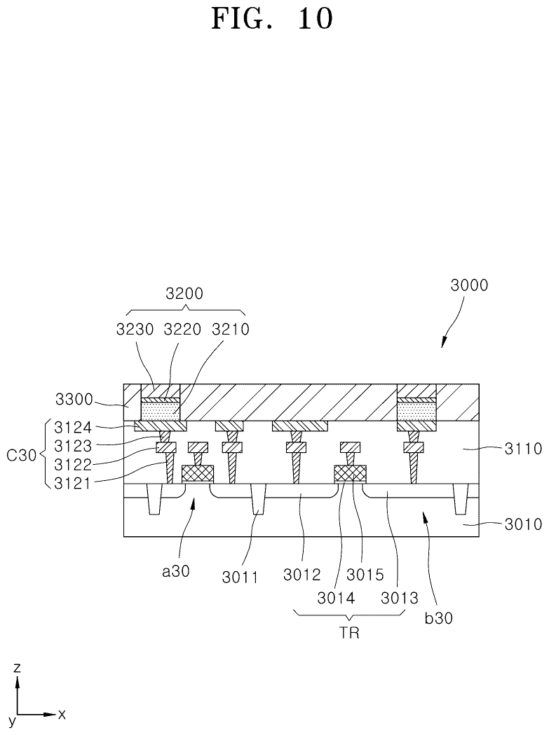

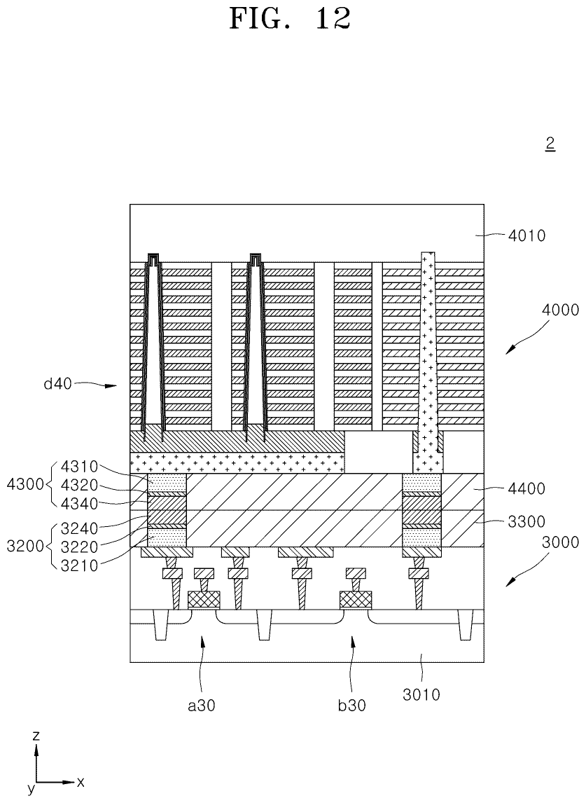

FIG. 10 through FIG. 12 are schematic cross-sectional views illustrating a method of fabricating a semiconductor device according to another embodiment of the present disclosure. A semiconductor device 2 illustrated in FIG. 12 may be a memory device including a plurality of memory cells and a memory cell driving circuit that controls the plurality of memory cells. As an example, the semiconductor device 2 may be a NAND-type flash memory device with a three-dimensional structure.

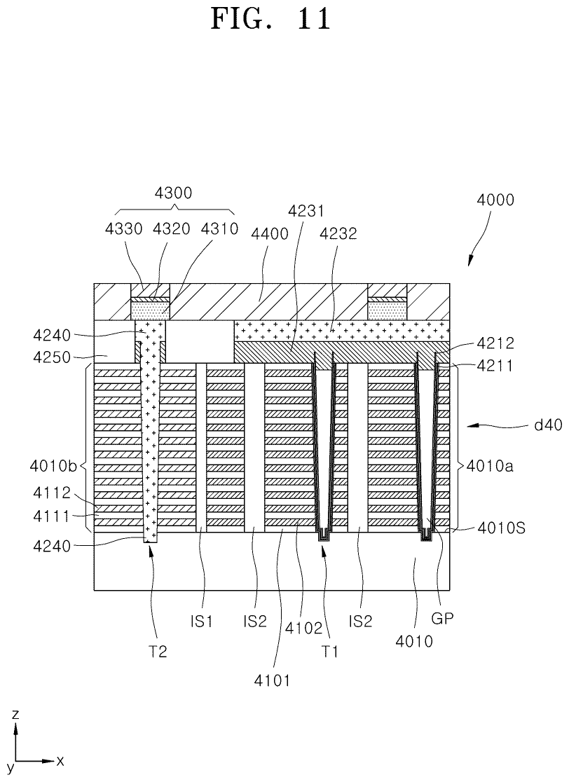

In an embodiment, a method of fabricating the semiconductor device 2 includes an operation of forming a first substrate structure 3000 including memory cell driving circuits a30 and b30 to be described with reference to FIG. 10, an operation of forming a second substrate structure 4000 including memory cell structures d40 to be described with reference to FIG. 11, and an operation of bonding the first substrate structure 3000 and the second substrate structure 4000 to each other to be described with reference to FIG. 12.

Referring to FIG. 10, the first substrate structure 3000 is formed through a semiconductor integration process. The first substrate structure 3000 includes a first substrate 3010, the memory cell driving circuits a30 and b30 disposed on the first substrate 3010, driving circuit wirings C30 electrically connected to the memory cell driving circuits a30 and b30 over the first substrate 3010, first connection structures 3200 electrically connected to the driving circuit wirings C30, and a first bonding insulation layer 3300 disposed in a lateral direction (for example, the x-direction or y-direction) from the first connection structures 3200. Each of the first connection structures 3200 includes a first pad layer 3210, a first electrode layer 3220, and a first bonding material layer 3230 that are sequentially stacked on the driving circuit wirings C30.

Referring to FIG. 10, the first substrate 3010 may be a wafer to which a semiconductor integrated circuit process can be applied. For example, the first substrate 3010 may be a silicon wafer doped with an n-type or p-type dopant. Although not shown, the first substrate 3010 may include a well region doped with an n-type or p-type dopant. Device isolation layers 3011 defining active regions are formed within the first substrate 3010. The device isolation layer 3011 may include an oxide layer, a nitride layer, or a combination thereof.

In an embodiment, the memory cell driving circuits include a source line driving circuit a30 connected to a source line of a memory cell, and a page buffer circuit b30 which is a peripheral circuit of the memory cell. Each of the source line driving circuit a30 and page buffer circuit b30 includes a field effect transistor TR including a first well region 3012, a second well region 3013, a gate dielectric layer 3014, and a gate electrode layer 3015. One of the first well region 3012 and second well region 3013 may function as a source region of the field effect transistor TR and the other may function as a drain region of the field effect transistor TR.

Referring to FIG. 10, an interlayer insulation structure 3110 covering the memory cell driving circuits a30 and b30 is disposed on the first substrate 3010. The interlayer insulation structure 3110 may include at least one layer of insulation layer. The driving circuit wirings C30 are disposed inside the interlayer insulation structure 3110. Each of the driving circuit wirings C30 includes a first circuit pattern layer 3122 and a second circuit pattern layer 3124 that are disposed on different planes. In addition, each of the driving circuit wirings C30 includes a first contact plug 3121 electrically connecting the first circuit pattern layer 3122 to the first and second well regions 3012 and 3013 and a second contact plug 3123 electrically connecting the first and second circuit pattern layers 3122 and 3124 to each other.

Referring to FIG. 10, the first connection structures 3200 are disposed over the interlayer insulation structure 3110 to be electrically connected to the second circuit pattern layer 3124. Each of the first connection structures 3200 includes a first pad layer 3210 that functions as a connection pad, a first electrode layer 3220 that functions as a heater electrode, and a first bonding material layer 3230 that functions as a preliminary bonding layer. The configurations of the first pad layer 3210, the first electrode layer 3220, and the first bonding material layer 3230 may be substantially the same as the configurations of the first pad layer 1220, the first electrode layer 1240, and the first bonding material layer 1250 described above with reference to FIG. 7, respectively. The first bonding insulation layer 3300 is disposed to surround the first connection structures 3200 over the interlayer insulation structure 3110. The configuration of the first bonding insulation layer 3300 may be substantially the same as the configuration of the first bonding insulation layer 1350 described above with reference to FIG. 7.

Referring to FIG. 11, the second substrate structure 4000 is formed through a semiconductor integration process. The second substrate structure 4000 includes a second substrate 4010, the memory cell structures d40 disposed on the second substrate 4010, second connection structures 4300 disposed over the memory cell structures d40, cell wirings 4231, 4232, and a vertical contact plug 4240 that electrically connect the memory cell structures d40 to the second connection structures 4300. In addition, the second substrate structure 4000 includes a second bonding insulation layer 4400 disposed in the lateral direction (for example, the x-direction or y-direction) from the second connection structures 4300. Each of the second connection structures 4300 includes a second pad layer 4310, a second electrode layer 4320, and a second bonding material layer 4330 that may be sequentially stacked over the cell wirings 4231, 4232, and the vertical contact plug 4240.

Referring to FIG. 11, the second substrate 4010 may be a wafer to which a semiconductor integrated circuit process can be applied. For example, the second substrate 4010 may be a silicon wafer doped with an n-type or p-type dopant. Although not shown, the second substrate 4010 may include a well region doped with an n-type or p-type dopant.

The memory cell structures d40 include cell gate structures 4010a and a contact plug structure 4010b that are disposed to be spaced apart from each other in the lateral direction (for example, the x-direction or y-direction that is parallel to a surface 4010S of the second substrate 4010). A first vertical insulation structure IS1 is disposed between the cell gate structure 4010a and the contact plug structure 4010b. The first vertical insulation structure IS1 separates the cell gate structure 4010a and the contact plug structure 4010b from each other. A second vertical insulation structure IS2 is disposed between neighboring cell gate structures 4010a. The second vertical insulation structure IS2 isolates the neighboring cell gate structures 4010a from each other.

Each of the cell gate structures 4010a includes an interlayer insulation layer 4101 and a gate electrode layer 4102 that are alternately stacked in the z-direction, which is vertical to the surface 4010S of the second substrate 4010. Each of the memory cell structures d40 includes a memory function layer 4211 and a channel layer 4212 that are disposed on a sidewall of a trench T1 penetrating the cell gate structure 4010a and the second substrate 4010.

Although not shown, the memory function layer 4211 may include a barrier insulation layer, a charge reservoir layer, and a charge tunnel layer that are sequentially disposed from the sidewall of the trench T1. The channel layer 4212 is disposed on the memory function layer 4211 and protrudes over the cell gate structure 4010a. The trench T1 in which the memory function layer 4211 and the channel layer 4212 are formed may be filled with an insulating gap-fill material GP.

A common source line structure 4231, 4232 is disposed as the cell wiring on the cell gate structure 4010a. As an example, the common source line structure 4231, 4232 includes a first conductor layer 4231, which is a doped semiconductor layer, and a second conductor layer 4232, which is a metal layer. The first conductor layer 4231 is in contact with the channel layer 4212, so that the common source line structure 4231, 4232 is electrically connected to the channel layer 4212.

The contact plug structure 4010b includes interlayer insulation layers 4111 and sacrificial insulation layers 4112 that are alternately stacked in the z-direction. The interlayer insulation layers 4111 are disposed at the same levels as the interlayer insulation layers 4101 of the cell gate structures 4010a. The sacrificial insulation layers 4112 are disposed at the same levels as the gate electrode layers 4102 of the cell gate structures 4010a.

Each of the contact plug structures 4010b includes a vertical contact plug 4240 that fills a trench T2 penetrating the contact plug structure 4010b and the second substrate 4010. The vertical contact plug 4240 extends to an upper portion of the contact plug structure 4010b. Each of the memory cell structures d40 includes a passivation layer 4250 to electrically insulate the vertical contact plug 4240 from the common source line structure 4231+4232.

Referring back to FIG. 11, the second connection structures 4300 are disposed on the cell wirings 4231, 4232, and the vertical contact plug 4240. Each of the second connection structures 4300 includes a second pad layer 4310 that functions as a connection pad, a second electrode layer 4320 that functions as a heater electrode, and a second bonding material layer 4330 that functions as a preliminary bonding layer. The configurations of the second pad layer 4310, the second electrode layer 4320, and the second bonding material layer 4330 may be substantially the same as the configurations of the second pad layer 2220, the second electrode layer 2240, and the second bonding material layer 2250 described above with reference to FIG. 8, respectively. The second bonding insulation layer 4400 is disposed to surround the second connection structures 4300 over the cell wirings 4231, 4232 and the vertical contact plug 4240. The configuration of the second bonding insulation layer 4400 may be substantially the same as the configuration of the second bonding insulation layer 2350 described above with reference to FIG. 8.

Referring to FIG. 12, by applying a rapid thermal treatment process, the first bonding material layer (3230 in FIG. 10) of the first substrate structure 3000 and the second bonding material layer (4330 in FIG. 11) of the second substrate structure 4000 are bonded to each other, and the first bonding insulation layer 3300 of the first substrate structure 3000 and the second bonding insulation layer 4400 of the second substrate structure 4000 are bonded to each other.

The rapid thermal treatment process may be performed by irradiating the first substrate structure 3000 and the second substrate structure 4000 with a heat source that performs rapid heating and cooling the first substrate structure 3000 and the second substrate structure 4000 that are in contact with each other. The first bonding material layer 3230 and the second bonding material layer 4330 are rapidly melted and then solidified between the first electrode layer 3220 and the second electrode layer 4320 by the heat source to form thermal bonds. Through this, as shown in FIG. 12, the first bonding material layer 3230 and the second bonding material layer 4330 are converted into the first bonding layer 3240 and the second bonding layer 4340, respectively, thereby enabling the first connection structures 3200 and the second connection structures 4300 to be bonded to each other. The rapid thermal treatment process may be substantially the same as the thermal treatment process using the heat source HS that performs rapid heating and cooling, described above with reference to FIG. 9.

By applying the above-described methods, a semiconductor device 2 according to the embodiment of the present disclosure can be fabricated. The semiconductor device 2 includes the first substrate structure 3000 and the second substrate structure 4000 bonded to each other. The first substrate structure 3000 includes the first substrate 3010, the memory cell driving circuits a30 and b30 disposed on the first substrate 3010, and the first connection structures 3200 disposed over the first substrate 3010 and electrically connected to the memory cell driving circuits a30 and b30. The second substrate structure 4000 includes the second substrate 4010, the memory cell structures d40 disposed on the second substrate 4010, and the second connection structures 4300 disposed over the second substrate 4010 and electrically connected to the memory cell structure d40. The first and second connection structures 3200 and 4300 include corresponding first and second pad layers 3210 and 4310, first and second electrode layers 3220 and 4320 containing graphene, and first and second bonding layers 3240 and 4340, respectively.

Concepts are disclosed in conjunction with various embodiments as described above. Those skilled in the art will understand that various modifications, additions, and substitutions are possible, without departing from the scope and spirit of the present disclosure. Accordingly, the embodiments disclosed in the present specification should not be considered from a restrictive standpoint but rather from an illustrative standpoint. The scope of the present disclosure is not limited to the above descriptions, and all of distinctive features within an equivalent scope should be construed as being included in the present disclosure.

What is claimed is:

1. A semiconductor device comprising a first stacked structure and a second stacked structure that are bonded to each other,
wherein the first stacked structure comprises a first base body and a first connection structure disposed over the first base body, and
the second stacked structure comprises a second base body and a second connection structure disposed over the second base body, and
wherein each of the first and second connection structures comprises:
a connection pad;
a carbon-based barrier layer disposed on the connection pad; and
a bonding layer disposed on the carbon-based barrier layer and coupling the first and second connection structures to each other.

2. The semiconductor device of claim 1, further comprising:
a first bonding insulation layer disposed over the first base body in a lateral direction from the first connection structure; and
a second bonding insulation layer disposed over the second base body in a lateral direction from the second connection structure and bonded to the first bonding insulation layer.

3. The semiconductor device of claim 1, wherein the carbon-based barrier layer blocks material movement between the connection pad and the bonding layer.

4. The semiconductor device of claim 1, wherein the carbon-based barrier layer comprises a single layer of graphene or multiple layers of graphene.

5. The semiconductor device of claim 1, wherein the carbon-based barrier layer has a thickness of 0.1 nm to 10 nm.

6. The semiconductor device of claim 1,
wherein the connection pad comprises at least one selected from the group consisting of copper (Cu), aluminum (Al), tungsten (W), titanium (Ti), tantalum (Ta), titanium nitride, tantalum nitride, and tungsten nitride, and
wherein the bonding layer comprises at least one selected from copper (Cu), a binary copper alloy, and a high-entropy alloy.

7. The semiconductor device of claim 6, wherein the binary copper alloy comprises copper-titanium (Cu—Ti) alloy or copper-aluminum (Cu-AI) alloy.

8. The semiconductor device of claim 6, wherein the high-entropy alloy is a metal alloy containing at least four metals selected from the group consisting of copper (Cu), nickel (Ni), iron (Fe), chromium (Cr), platinum (Pt), silver (Ag), palladium (Pd), cobalt (Co), titanium (Ti), zirconium (Zr), and hafnium (Hf).

9. A semiconductor device comprising a first substrate structure and a second substrate structure that are bonded to each other,
wherein the first substrate structure comprises:
a first substrate;
a memory cell driving circuit disposed on the first substrate; and
a first connection structure disposed over the first substrate and electrically connected to the memory cell driving circuit,
wherein the second substrate structure comprises:
a second substrate;
a memory cell structure disposed on the second substrate; and
a second connection structure disposed over the second substrate and electrically connected to the memory cell structure, and
wherein each of the first and second connection structures comprises:
a connection pad;
a carbon-based barrier layer disposed on the connection pad; and
a bonding layer disposed on the carbon-based barrier layer and coupling the first and second connection structures to each other.

10. The semiconductor device of claim 9,
wherein the connection pad comprises at least one selected from the group consisting of copper (Cu), aluminum (Al), tungsten (W), titanium (Ti), tantalum (Ta), titanium nitride, tantalum nitride, and tungsten nitride, and
wherein the bonding layer comprises at least one selected from copper (Cu), a binary copper alloy, and a high-entropy alloy.
